(19) United States
(12) Patent Application Publication
(10) Pub. No.: US 2023/0088569 A1
(43) Pub. Date: Mar. 23, 2023

(54) RADIO-FREQUENCY INTEGRATED CIRCUITS (RFICS) INCLUDING A POROSIFIED SEMICONDUCTOR ISOLATION REGION TO REDUCE NOISE INTERFERENCE AND RELATED FABRICATION METHODS

(71) Applicant: QUALCOMM Incorporated, San Diego, CA (US)

(72) Inventors: Ranadeep Dutta, Del Mar, CA (US); Jonghae Kim, San Diego, CA (US); Je-Hsiung Lan, San Diego, CA (US)

(21) Appl. No.: 17/482,733

(22) Filed: Sep. 23, 2021

(51) Int. Cl. H01L 27/12; H01L 23/66; H01L 21/762; H01L 21/84

(52) U.S. Cl. CPC H01L 27/1203; H01L 23/66; H01L 21/76245; H01L 21/84

(57) ABSTRACT

Radio frequency (RF) circuits generate noise that can interfere with other RF circuits on the same semiconductor die. An isolation material disposed in an isolation region between a first active region of a first RF circuit and a second active region of a second RF circuit comprises a porosified region of the semiconductor material of the semiconductor die. The isolation material (e.g., porosified material) has a higher resistivity and lower permittivity than the semiconductor material to reduce transmission of noise interference between the first RF circuit and the second RF circuit. The isolation material in the isolation region of the semiconductor material comprises a porosity in the range 20% to 50% higher than the porosity of the semiconductor material in the first and second active regions. The porosified region has a lower permittivity and a higher resistivity than the non-porosified region to protect against the transmission of noise interference.

### BACKGROUND

### I. Field of the Disclosure

The field of the disclosure relates to radio-frequency integrated circuits, including a plurality of radio frequency (RF) circuits on a semiconductor die, and more particularly to noise interference between the RF circuits.

### II. Background

High-speed telecommunication has become ubiquitous in our society. Many electronic devices employ one or more forms of wired and/or wireless communication to access other devices directly or via telecommunications networks. Telecommunications devices capable of two-way communication include circuits for both transmission and reception of radio frequency signals. A radio frequency (RF) integrated circuit (IC) (RFIC) is an IC employed in devices for communications. An RFIC operates in frequency ranges suitable for communications and may include one or more transceivers, each including one or more transmitter circuits and one or more receiver circuits in a single semiconductor die. A transmitter circuit in a transceiver employs a power amplifier (PA) to amplify a signal received at a low-power level and generates a high-power signal for transmission over a wired or wireless medium. One measure of the quality of a PA is a signal-to-noise ratio (SNR) of the generated output signal, but even high-quality PAs generate some noise interference because, in addition to amplifying the low-power signal, a PA also unintentionally amplifies and generates unwanted signal noise.

In contrast, a receiver circuit in a transceiver receives a low-power signal transmission that includes signal noise (electromagnetic interference (EMI)) and radio frequency interference (RFI), which may include undesired RF signals from various sources. The SNR of a received signal may be very low, depending on many factors. The receiver circuit includes a low-noise amplifier (LNA) for the purpose of isolating and amplifying a weak desired RF signal while excluding as much interference as possible from the received transmission to produce an output signal with a high SNR that can be used for signal processing or further amplification. Therefore, one of the tasks of an LNA is to filter out noise interference from within the same transceiver.

In addition to PAs, other RF circuits, including driver amplifiers, voltage-controlled oscillators (VCOs), phase locked loops (PLLs), and mixers, may be a source of noise interference from within the same device. One of the challenges of developers of an RFIC is to reduce or avoid interference among the respective RF circuits.

### SUMMARY OF THE DISCLOSURE

Exemplary aspects disclosed in the detailed description include radio-frequency integrated circuits (RFICs), including a porosified semiconductor isolation region to reduce noise interference. Related fabrication methods are also disclosed. Radio frequency (RF) circuits, including active digital components and passive analog components operating at radio frequencies, generate noise that can interfere with other RF circuits. The active digital components include transistors disposed in active regions of semiconductor material on a surface of a semiconductor die. In an exemplary aspect, an isolation material disposed in an isolation region between a first active region of a first RF circuit and a second active region of a second RF circuit comprises a porosified region of the semiconductor material of the semiconductor die. The isolation material comprises a same composition as the semiconductor material in the first and second active regions but has a higher fraction of voids over the total volume of the isolation material compared to the fraction of voids over the total volume of semiconductor material in the first and second active regions. The isolation material is provided between the first and second active regions to increase resistivity and lower permittivity in these regions, to reduce transmission of noise interference and capacitance between the first RF circuit and the second RF circuit. The isolation material in the isolation region of the semiconductor material) comprises a porosity that is at least twenty percent (20%) higher than a porosity of the semiconductor material in the first and second active regions. The increased porosity in the porosified region reduces permittivity and increases resistivity compared to the non-porosified region. In some examples, the semiconductor material in the first and second active regions comprises crystalline (e.g., monocrystalline) silicon, and the isolation material comprises crystalline silicon that has been porosified. In some examples, the porosity of the isolation material is between twenty percent (20%) and fifty percent (50%) higher than the porosity of the crystalline silicon in the first and second active regions. In some examples, the passive components of the RF circuits comprise matching networks disposed on additional porosified regions of the semiconductor material to improve the isolation of the matching networks to improve the Q factor of the matching networks.

In a first exemplary aspect, an RFIC, comprising a semiconductor die, and a first RF circuit comprising at least one first transistor disposed in a first active region of the semiconductor die. The RFIC comprises a second RF circuit comprising at least one second transistor disposed in a second active region of the semiconductor die, and an isolation material in an isolation region of the semiconductor die between the first active region and the second active region and configured to electrically isolate the first active region from the second active region. In the RFIC, each of the first active region and the second active region comprises a semiconductor material comprising a first porosity, and the isolation material comprises the semiconductor material comprising a second porosity at least twenty percent (20%) higher than the first porosity.

In another exemplary aspect, a method of fabricating an RFIC is disclosed. The method comprises forming a semiconductor die, forming a first RF circuit comprising at least one first transistor in a first active region of the semiconductor die, and forming a second RF circuit comprising at least one second transistor in a second active region of the semiconductor die. The method comprises forming an isolation material in an isolation region of the semiconductor die between the first active region and the second active region, the isolation material configured to electrically isolate the first active region from the second active region. In the method, each of the first active region and the second active region comprises a semiconductor material comprising silicon and the isolation material comprises porous silicon with porosity range between 20% and 50%.

In another exemplary aspect, an RFIC, comprising a semiconductor die, a first RF circuit comprising at least one first transistor disposed in a first active region of the semiconductor die, and a second RF circuit comprising at least one second transistor disposed in a second active region of the semiconductor die. The RFIC comprises an isolation material in an isolation region of the semiconductor die between the first active region and the second active region and configured to electrically isolate the first active region from the second active region. In the RFIC, each of the first active region and the second active region comprises a semiconductor material and the isolation material comprises a porosified region of the semiconductor material.

In another exemplary aspect, a method of fabricating an RFIC is disclosed. The method comprises forming a semiconductor die, forming a first RF circuit comprising at least one first transistor in a first active region of the semiconductor die, and forming a second RF circuit comprising at least one second transistor in a second active region of the semiconductor die. The method comprises forming an isolation material in an isolation region of the semiconductor die between the first active region and the second active region and configured to electrically isolate the first active region from the second active region. In the method, each of the first active region and the second active region comprises a semiconductor material, and the isolation material comprises a porosified region of the semiconductor material.

### BRIEF DESCRIPTION OF THE FIGURES

FIG. 1A is an illustration of a top view of a radio frequency (RF) integrated circuit (IC) (RFIC), including an isolation material in an isolation region to reduce interference between a first RF circuit in a first active region of a semiconductor die from a second RF circuit in a second active region of the semiconductor die;

FIG. 1B is a cross-sectional side view of the RFIC in FIG. 1A, including the isolation region between the first and second RF circuits and additional isolation regions for respective matching networks of the first and second RF circuits;

FIG. 2 is a cross-sectional side view of a conventional RFIC including first and second RF circuits but not including the isolation regions illustrated in FIGS. 1A and 1B;

FIGS. 3A-3E are illustrations of stages in a process of fabricating an RFIC, including an isolation region to reduce interference between first and second RF circuits, as shown in FIGS. 1A and 1B;

FIGS. 4A-4E are a flowchart illustrating the stages in the process of fabricating the RFIC illustrated in FIGS. 3A-3E;

FIG. 5 is a block diagram of an exemplary wireless communications device that includes an RFIC, including an isolation material in an isolation region in a semiconductor die to reduce noise interference between RF circuits in active regions of the semiconductor die, as illustrated in FIGS. 1A, 1B, and 3A-3E; and

FIG. 6 is a block diagram of an exemplary processor-based system that can include an RFIC including an isolation material in an isolation region in a semiconductor die to reduce noise interference between RF circuits in active regions of the semiconductor die as illustrated in FIGS. 1A, 1B, and 3A-3E, and according to any of the aspects disclosed herein.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Exemplary aspects disclosed in the detailed description include radio-frequency integrated circuits (RFICs), including a porosified semiconductor isolation region to reduce noise interference. Related fabrication methods are also disclosed. Radio frequency (RF) circuits, including active digital components and passive analog components operating at radio frequencies, generate noise that can interfere with other RF circuits. The active digital components include transistors disposed in active regions of semiconductor material on a surface of a semiconductor die. In an exemplary aspect, an isolation material disposed in an isolation region between a first active region of a first RF circuit and a second active region of a second RF circuit comprises a porosified region of the semiconductor material of the semiconductor die.

The isolation material comprises a same composition as the semiconductor material in the first and second active regions but has a higher fraction of voids over the total volume of the isolation material compared to the fraction of voids over the total volume of semiconductor material in the first and second active regions. The isolation material is provided between the first and second active regions to increase resistivity and lower permittivity in these regions, to reduce transmission of noise interference and capacitance between the first RF circuit and the second RF circuit. The isolation material in the isolation region of the semiconductor material comprises a porosity that is at least twenty percent (20%) higher than a porosity of the semiconductor material in the first and second active regions. The increased porosity in the porosified region reduces permittivity and increases resistivity compared to the non-porosified region. In some examples, the semiconductor material in the first and second active regions comprises crystalline silicon, and the isolation material comprises crystalline silicon that has been porosified. In some examples, the porosity of the isolation material is between twenty percent (20%) and fifty percent (50%) greater than the porosity of the crystalline silicon in the first and second active regions. In some examples, the passive components of the RF circuits comprise matching networks disposed on additional porosified regions of the semiconductor material to improve the isolation of the matching networks to improve the Q factor of the matching networks.

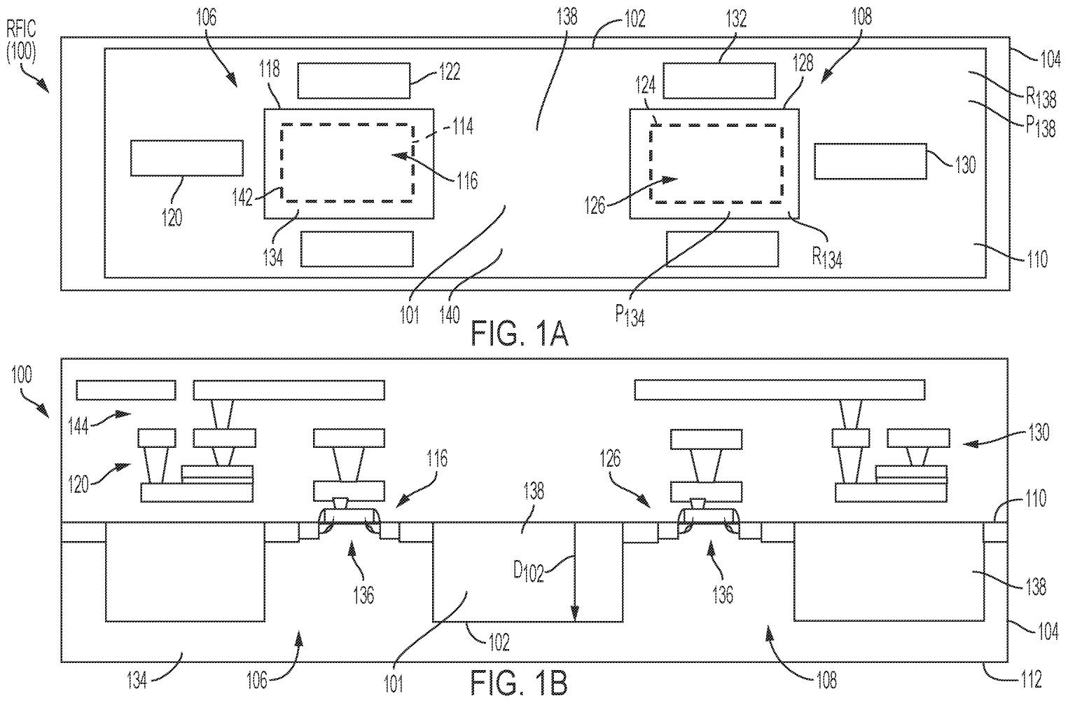

FIG. 1A is a top view of an exemplary RFIC 100, including an isolation material 101 in an isolation region 102 of a semiconductor die 104 employed to reduce noise interference (e.g., cross-talk, leakage currents, electromagnetic fields, etc.) between a first RF circuit 106 and a second RF circuit 108 through the semiconductor die 104. FIG. 1B is a cross-sectional side view of the RFIC 100 in FIG. 1A showing that the isolation region 102 extends to a depth D₁₀₂ from a front surface 110 in the semiconductor die 104, creating a barrier to the noise interference between the first RF circuit 106 and the second RF circuit 108. In some examples, the semiconductor die 104 is thinned to a thickness corresponding to a depth of the isolation region 102, such that the isolation region 102 extends to a back surface 112 of the semiconductor die 104, eliminating a path through the semiconductor die 104 under the isolation region 102.

The first RF circuit 106 and the second RF circuit 108 include a first active circuit 114 that includes first transistors 116 disposed in a first active region 118 of the front surface 110 of the semiconductor die 104. The first RF circuit 106 also includes a first passive component circuit 120 that may comprise at least one first matching network 122. The second RF circuit 108 includes a second active circuit 124 including second transistors 126 disposed in a second active region 128 of the front surface 110 of the semiconductor die 104. The second RF circuit 108 also includes a second passive component circuit 130 that may comprise at least one second matching network 132. The first RF circuit 106 and the second RF circuit 108 operate at radio frequencies and generate noise that can interfere with the operation of other RF circuits. In some examples, the first RF circuit 106 generates more noise and greater magnitude noise than the second RF circuit 108. In this regard, the first RF circuit 106 may be referred to as a noise-generating circuit. In contrast, the second RF circuit 108 may generate less noise and noise of a lower magnitude and may also be more susceptible to noise interference than the first RF circuit 106. Thus, the second RF circuit 108 is referred to as a noise-sensitive circuit. As an example of a noise-generating circuit, the first RF circuit 106 may be a power amplifier (PA) employed to amplify signals for transmission. An example of a noise-sensitive circuit, the second RF circuit 108, may comprise a low-noise amplifier employed to filter and amplify weak signals or frequencies of a received transmission. Other examples of noise-generating circuits include driver amplifiers, voltage-controlled oscillators (VCOs), phase locked loops (PLLs), and mixers.

In the first and second active regions 118 and 128 in the example in FIGS. 1A and 1B, the semiconductor die 104 comprises a semiconductor material 134 (e.g., silicon) which has a crystalline structure (e.g., monocrystalline bulk silicon) employed in channel regions 136 of the first and second transistors 116, 126. The isolation region 102 in FIGS. 1A and 1B comprises porosified semiconductor material (“isolation material 101”) comprising the semiconductor material 134 that has been made more porous (i.e., porosified) in a porosification process. The most common methods for porosification of the semiconductor material 134 (e.g., silicon) are anodization and stain etching. Porosification of the semiconductor material 134 etches matter out of a microstructure of the semiconductor material 134, introducing nanopores into the microstructure, and generating the isolation material 101. The introduction of the nanopores causes the isolation material 101 to have a higher ratio of the pore volume to a total volume of the isolation material than a ratio of pore volume to a total volume of the semiconductor material 134. Significant benefits of porosification of the semiconductor material 134 include changes to the electrical properties of the isolation material 101 compared to the (non-porosified) semiconductor material 134. For example, a resistivity R₁₃₈ of the isolation material 101 is greater than a resistivity R₁₃₄ of the semiconductor material 134. As an example, crystalline silicon that is 30% porosified has a resistivity of approximately 107 ohm-centimeters, and crystalline silicon that is 60% porosified has a resistivity of approximately 109 ohm-centimeters. In addition, a permittivity P₁₃₉ of the porosified semiconductor material 101 is lower than a permittivity P₁₃₄ of the semiconductor material 134. As an example, crystalline silicon that is 30% porosified has a permittivity of approximately 8.5, and crystalline silicon that is 60% porosified has a permittivity approximately in the range of 4.0 to 5.0. In another aspect, the loss tangent of 50% porous silicon is less than 0.001 at 20 GHz, which is approximately 1/20^{th} of the loss tangent of crystalline silicon. The porosification process porosifies the semiconductor material 134 to transform the bulk, monocrystalline semiconductor material 134 into the isolation material 101 to the depth D₁₀₂ of the isolation region 102. The depth D₁₀₂ can extend in a range of fifty to one hundred fifty (50-150) micrometers (μm) in a direction orthogonal to the front surface 110 of the semiconductor die 104. After formation of the first transistors 116 in the first active region 118 and the second transistors 126 in the second active region 128, which may include existing front-end-of-line (FEOL) processes for fabricating complementary metal-oxide-semiconductor (CMOS) circuits, the process of porosifying the isolation region 102 may be inserted into the existing process flow with few to no changes to a previously qualified process for fabricating the first active circuit 114 and the second active circuit 124. The porosification process may be performed prior to a back-end-of-line (BEOL) process in which the first passive component circuit 120 and the second passive component circuit 130 are formed on the front surface 110.

The first passive component circuit 120 and the second passive component circuit 130 each include, for example, one or more capacitors, inductors, and/or resistors 144. To reduce cross-talk in the RFIC 100 that can affect the first and second matching networks 122, 132, the first and second matching networks 122, 132 are also disposed on the isolation material 101. In this regard, the isolation material 101 may be formed in the semiconductor die 102 to surround the first and second active regions 118, 128. Alternatively, each of the first and second passive component circuits 120, 130 could be formed on isolated island regions or localized “tubs” of the isolation material (not shown) formed in the semiconductor die 102. Noise interference in the first and second matching networks 122, 132 is reduced due to the high resistivity R₁₃₈ and low permittivity P₁₃₈ of the isolation material 101. The increased resistivity improves electrical isolation of the first and second passive component circuits 120, 130, which improves their Q value and the performance of the first and second RF circuits 106, 108. An increase in resistivity reduces the magnitude of any noise that may be transmitted through the semiconductor die 104 from the first RF circuit 106 to the second RF circuit 108, and the corresponding decrease in permittivity reduces capacitances that may otherwise occur between the first RF circuit 106 and the second RF circuit 108.

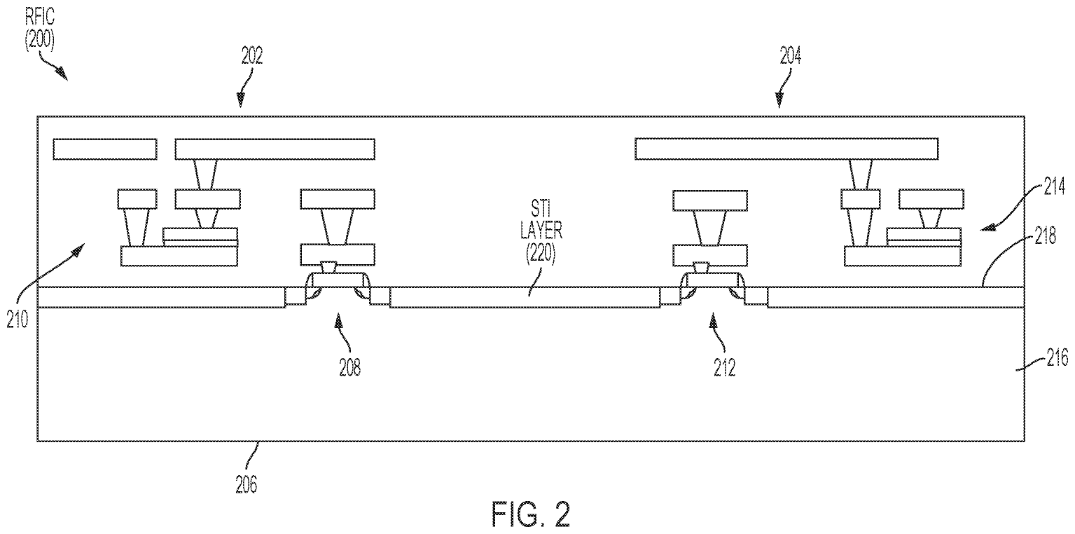

FIG. 2 is a cross-sectional side view of a conventional RFIC 200 provided for comparison. The RFIC 200 includes a first RF circuit 202 and a second RF circuit 204 formed on a semiconductor substrate 206. The first RF circuit 202 includes a first active circuit 208 and a first passive component circuit 210 disposed on the semiconductor substrate 206. The second RF circuit 204 includes a second active circuit 212 and a second passive component circuit 214 on the semiconductor substrate 206. The first RF circuit 202 and the second RF circuit 204 are formed on the semiconductor substrate 206 comprising a semiconductor material 216. As the semiconductor material is a “semiconductor” (i.e., not a low-resistivity material), electrical signals can be transmitted through the semiconductor die 202. Without a barrier, noise interference can be transmitted through the semiconductor material 216 between first active circuit 208 and the second RF circuit 212 disposed in a front surface 218. To isolate the on-chip components, a shallow trench isolation (STI) layer 220 is first formed in the front surface 218 of the semiconductor substrate 206.

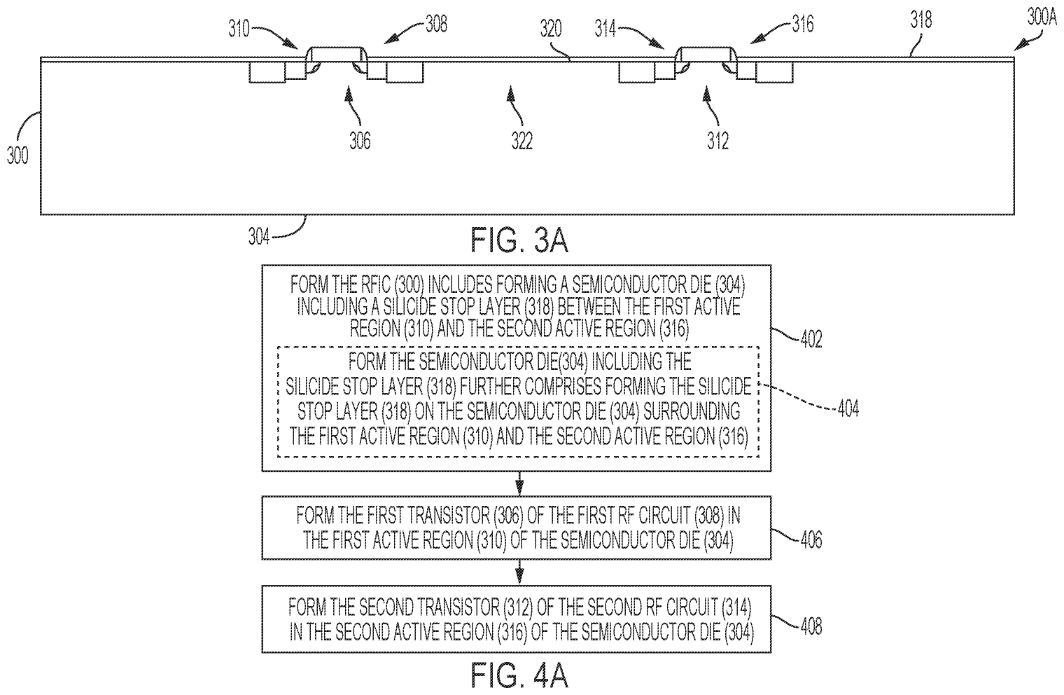

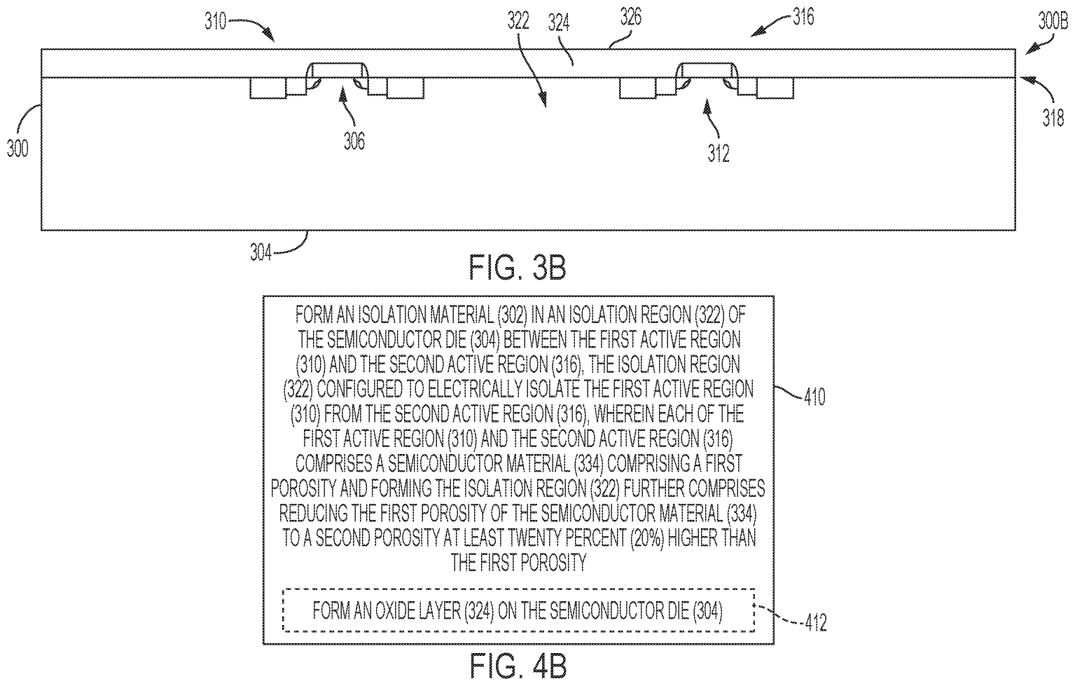

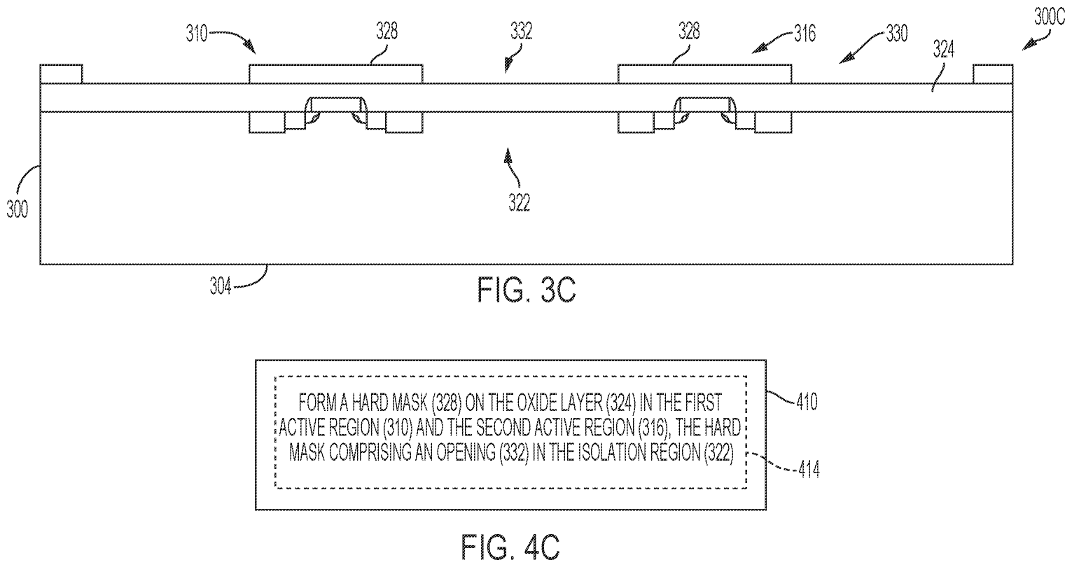

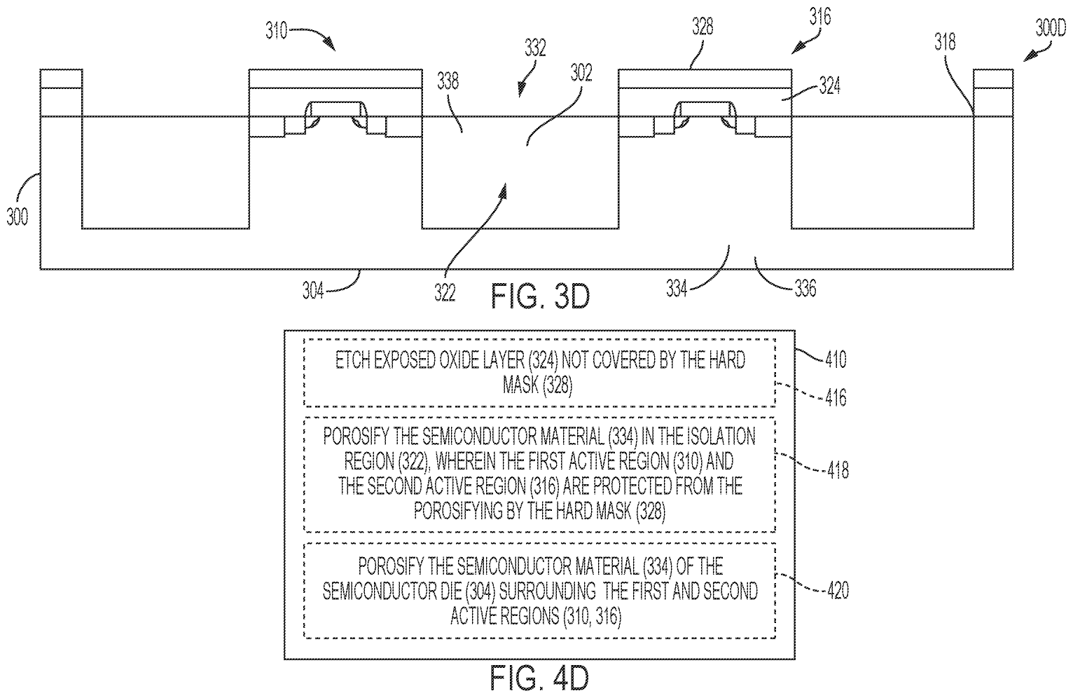

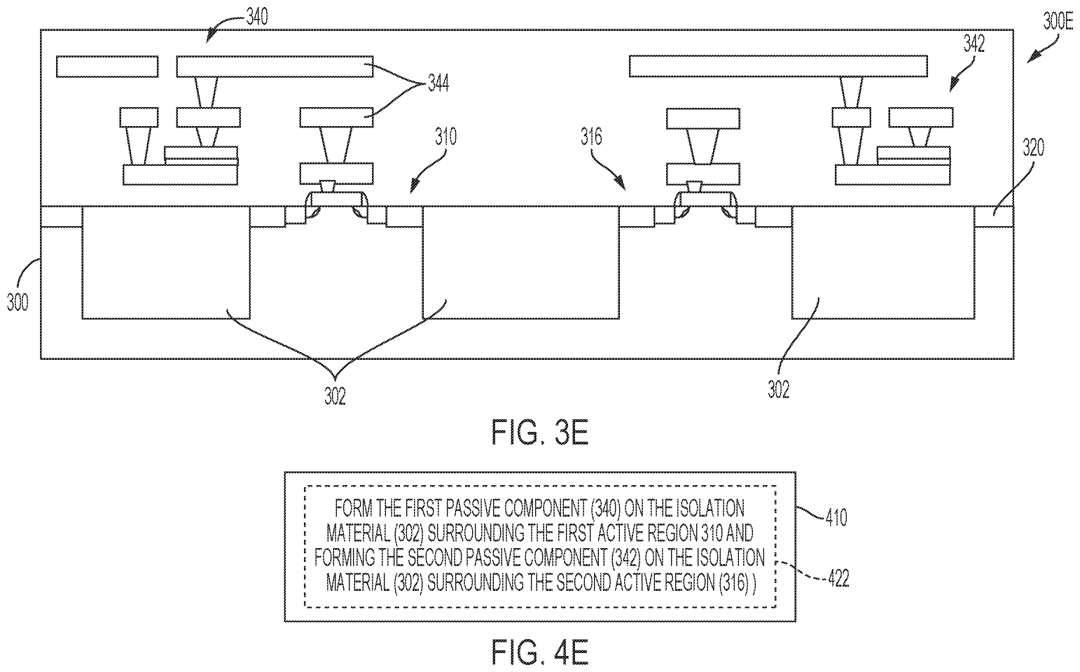

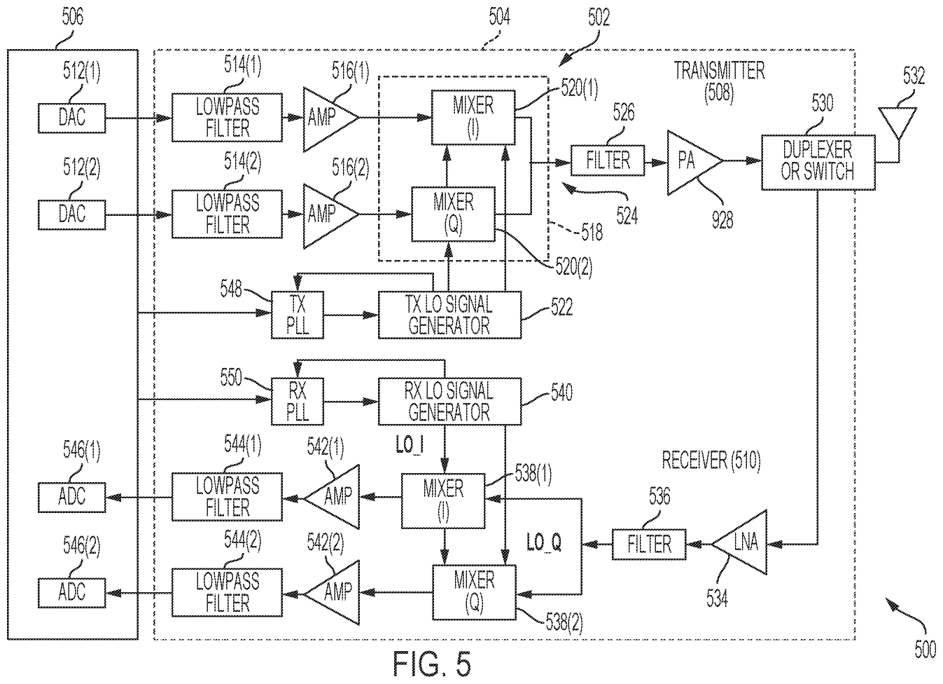

FIGS. 3A-3E are cross-sectional side views illustrating an RFIC 300 in stages 300A-300E during a process of fabricating an isolation material 302 in a semiconductor die 304. FIGS. 4A-4E are a flowchart illustrating stages 400A-400E of a process 400 of fabricating the RFIC 300, with reference to FIGS. 3A-3E. In FIG. 3A, the RFIC 300 in stage 300A comprises the semiconductor die 304 at a stage of an existing CMOS fabrication process in which at least a first transistor 306 of a first RF circuit 308 is formed in a first active region 310 of the semiconductor die 304, and at least a second transistor 312 of a second RF circuit 314 is formed in a second active region 316 of the semiconductor die 304. The first and second transistors 306 and 312 are formed in the first active region 310 and the second active region 316 in the same steps of the CMOS fabrication process, which include formation of source/drain regions and an anneal step. Employing a mask and an etching process, the silicide stop layer 318, in the example in FIGS. 3A-3E, is also disposed on the front surface 320 surrounding the first and second active regions 310, 316 to correspond to the isolation material 101 surrounding the first and second active regions 118, 128 in FIG. 1A. The silicide stop layer 318 stops silicidation in areas covered by the silicide stop layer 318, such as the first and second active regions 310, 316, and may comprise a silicon dioxide layer (e.g., SiO₂) or a combination of a silicon dioxide layer and a silicon nitride layer (e.g., SiO₂+Si₃N₄). In this regard, the process 400 of forming the RFIC 300 includes forming a semiconductor die (304), including a silicide stop layer (318) between the first active region (310) and the second active region (316) (block 402). Forming the semiconductor die (304), including the silicide stop layer (318), further includes forming the silicide stop layer (318) on the semiconductor die (304) to surround the first active region (310) and the second active region (316) (block 404).

The process 400 includes forming the first transistor (306) of the first RF circuit (308) in the first active region (310) of the semiconductor die (304) (block 406) and forming the second transistor (312) of the second RF circuit (314) in the second active region (316) of the semiconductor die (304) (block 408).

FIG. 3B is a cross-sectional side view of the RFIC 300 in the stage 300B of fabrication in which an oxide layer 324 is disposed on the semiconductor die 304 to cover the first and second transistors 306, 312 in the first and second active regions 310, 316, respectively, and cover the silicide stop layer 318. The oxide layer 324 may be a silicon dioxide (SiO₂) layer that provides protection to the first and second transistors 306, 312, and forms a continuous surface 326 on the semiconductor die 304. The process 400 includes, in FIGS. 4B-4E, forming the isolation material 302 (see FIG. 3D) in an isolation region (322) of the semiconductor die 304 between the first active region (310) and the second active region (316), the isolation region (322) configured to electrically isolate the first active region (310) from the second active region (316), wherein each of the first active region (310) and the second active region (316) comprises a semiconductor material (334) comprising a first porosity and forming the isolation region (322) further comprises increasing the first porosity of the semiconductor material (334) to a second porosity at least twenty percent (20%) higher than the first porosity (block 410). In stage 300B of fabrication, the process 400 includes forming an oxide layer (324) on the semiconductor die (304) (block 412).

FIG. 3C is a cross-sectional side view of the RFIC 300 in the stage 300C of fabrication in which a hard mask 328 is disposed in a pattern 330 on the oxide layer 324. In the pattern 330, the hard mask 328 is disposed on the first and second active regions 310, 316 in which porosification is not desired. The hard mask 328 protects the first and second active regions 310, 316 from the effects of the porosification process. A typical hard mask material is LPCVD-deposited silicon nitride, which is resistant to etching by HF. The pattern 330 includes an opening 332 between the first and second active regions 310, 316 to allow the semiconductor die 304 to be porosified. The pattern 330 may include forming the hard mask 328 in other areas of the semiconductor die 304 in which porosification is not desired and providing openings in areas in which porosification is desired, such as surrounding the first and second active regions 310, 316. The process 400 in FIG. 4C includes forming a hard mask (328) on the oxide layer (324) in the first active region (310) and the second active region (316), the hard mask comprising an opening (332) in the isolation region (322) (block 414).

FIG. 3D is a cross-sectional side view of the RFIC 300 in the stage 300D of fabrication in which the oxide layer 324 and the silicide stop layer 318 are removed in the opening 332 before the porosification process. In addition, a semiconductor material 334 of the semiconductor die 304 having a first porosity 336 has been porosified to become the isolation material 302 (porosified semiconductor material) having a second porosity 338 that is in a range of twenty percent (20%) to fifty percent (50%) higher than the first porosity 336. The process 400 in FIG. 4D includes etching exposed oxide layer (324) not covered by the hard mask (328) (block 416). The process 400 in FIG. 4D further includes porosifying the semiconductor material (334) in the isolation region (322), wherein the first active region (310) and the second active region (316) are protected from the porosifying by the hard mask (328) (block 418). The process 400 may include porosifying the semiconductor material (334) of the semiconductor die (304) surrounding the first and second active regions (310, 316) (block 420).

FIG. 3E is a cross-sectional side view of the RFIC 300 in the stage 300E of fabrication in which the hard mask 328 and the oxide layer 324 (see FIG. 3D) have been removed from the first and second active regions 310, 316, as well as from any other location on the front surface 320 on which the hard mask 328 was formed. Resuming fabrication in a BEOL process, a first passive component circuit 340 of the first RF circuit 308 and a second passive component circuit 342 of the second RF circuit 314 are formed on the isolation material 302 around the first and second active regions 310, 316 as interconnect layers 344 are formed on the semiconductor die 302. The process 400 in FIG. 4E includes forming the first passive component (340) on the isolation material (302) surrounding the first active region (310) and forming the second passive component (342) on the isolation material (302) surrounding the second active region (316) (block 422).

FIG. 5 illustrates an exemplary wireless communications device 500 that includes RF components formed from one or more ICs 502 and can include an RFIC including an isolation material in an isolation region in a semiconductor die to reduce noise interference between RF circuits in active regions of the semiconductor die as illustrated in FIGS. 1A, 1B, and 3A-3E, and according to any of the aspects disclosed herein. The wireless communications device 500 may include or be provided in any of the above-referenced devices, as examples. As shown in FIG. 5, the wireless communications device 500 includes a transceiver 504 and a data processor 506. The data processor 506 may include a memory to store data and program codes. The transceiver 504 includes a transmitter 508 and a receiver 510 that support bi-directional communications. In general, the wireless communications device 500 may include any number of transmitters 508 and/or receivers 510 for any number of communication systems and frequency bands. All or a portion of the transceiver 504 may be implemented on one or more analog ICs, RFICs, mixed-signal ICs, etc.

The transmitter 508 or the receiver 510 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 500 in FIG. 5, the transmitter 508 and the receiver 510 are implemented with the direct-conversion architecture.

In the transmit path, the data processor 506 processes data to be transmitted and provides I and Q analog output signals to the transmitter 508. In the exemplary wireless communications device 500, the data processor 506 includes digital-to-analog converters (DACs) 512(1), 512(2) for converting digital signals generated by the data processor 506 into the I and Q analog output signals, e.g., I and Q output currents, for further processing.

Within the transmitter 508, lowpass filters 514(1), 514(2) filter the I and Q analog output signals, respectively, to remove undesired signals caused by the prior digital-to-analog conversion. Amplifiers (AMPs) 516(1), 516(2) amplify the signals from the lowpass filters 514(1), 514(2), respectively, and provide I and Q baseband signals. An upconverter 518 upconverts the I and Q baseband signals with I and Q transmit (TX) local oscillator (LO) signals from a TX LO signal generator 522 through mixers 520(1), 520(2) to provide an upconverted signal 524. A filter 526 filters the upconverted signal 524 to remove undesired signals caused by the frequency upconversion as well as noise in a receive frequency band. A power amplifier (PA) 528 amplifies the upconverted signal 524 from the filter 526 to obtain the desired output power level and provides a transmit RF signal. The transmit RF signal is routed through a duplexer or switch 530 and transmitted via an antenna 532.

In the receive path, the antenna 532 receives signals transmitted by base stations and provides a received RF signal, which is routed through the duplexer or switch 530 and provided to a low noise amplifier (LNA) 534. The duplexer or switch 530 is designed to operate with a specific receive (RX)-to-TX duplexer frequency separation, such that RX signals are isolated from TX signals. The received RF signal is amplified by the LNA 534 and filtered by a filter 536 to obtain a desired RF input signal. Downconversion mixers 538(1), 538(2) mix the output of the filter 536 with I and Q RX LO signals (i.e., LO_I and LO_Q) from an RX LO signal generator 540 to generate I and Q baseband signals. The I and Q baseband signals are amplified by AMPs 542(1), 542(2) and further filtered by lowpass filters 544(1), 544(2) to obtain I and Q analog input signals, which are provided to the data processor 506. In this example, the data processor 506 includes analog-to-digital converters (ADCs) 546(1), 546(2) for converting the analog input signals into digital signals to be further processed by the data processor 506.

In the wireless communications device 500 of FIG. 5, the TX LO signal generator 522 generates the I and Q TX LO signals used for frequency upconversion, while the RX LO signal generator 540 generates the I and Q RX LO signals used for frequency downconversion. Each LO signal is a periodic signal with a particular fundamental frequency. A TX phase-locked loop (PLL) circuit 548 receives timing information from the data processor 506 and generates a control signal used to adjust the frequency and/or phase of the TX LO signals from the TX LO signal generator 522. Similarly, an RX PLL circuit 550 receives timing information from the data processor 506 and generates a control signal used to adjust the frequency and/or phase of the RX LO signals from the RX LO signal generator 540.

Wireless communications devices 500 that can each include an RFIC including an isolation material in an isolation region in a semiconductor die to reduce noise interference between RF circuits in active regions of the semiconductor die as illustrated in FIGS. 1A, 1B, and 3A-3E, and according to any of the aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

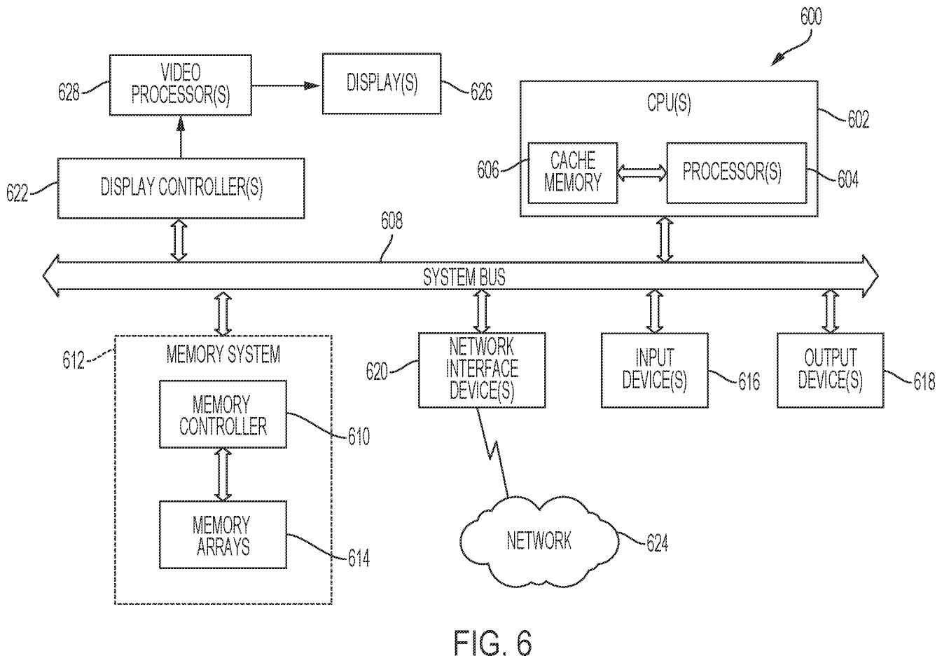

In this regard, FIG. 6 illustrates an example of a processor-based system 600 including an RFIC including an isolation material in an isolation region in a semiconductor die to reduce noise interference between RF circuits in active regions of the semiconductor die as illustrated in FIGS. 1A, 1B, and 3A-3E, and according to any aspects disclosed herein. In this example, the processor-based system 600 includes one or more central processor units (CPUs) 602, which may also be referred to as CPU or processor cores, each including one or more processors 604. The CPU(s) 602 may have cache memory 606 coupled to the processor(s) 604 for rapid access to temporarily stored data. The CPU(s) 602 is coupled to a system bus 608 and can intercouple master and slave devices included in the processor-based system 600. As is well known, the CPU(s) 602 communicates with these other devices by exchanging address, control, and data information over the system bus 608. For example, the CPU(s) 602 can communicate bus transaction requests to a memory controller 610 as an example of a slave device. Although not illustrated in FIG. 6, multiple system buses 608 could be provided; wherein each system bus 608 constitutes a different fabric.

Other master and slave devices can be connected to the system bus 608. As illustrated in FIG. 6, these devices can include a memory system 612 that includes the memory controller 610 and one or more memory arrays 614, one or more input devices 616, one or more output devices 618, one or more network interface devices 620, and one or more display controllers 622, as examples. Any of the output devices 618 and the network interface devices 620 can include an RFIC including an isolation region in a semiconductor die to reduce noise interference between RF circuits in active regions of the semiconductor die as illustrated in FIGS. 1A, 1B, and 3A-3E, and according to any of the aspects disclosed herein. The input device(s) 616 can include any type of input device, including, but not limited to, input keys, switches, voice processors, etc. The output device(s) 618 can include any type of output device, including, but not limited to, audio, video, other visual indicators, etc. The network interface device(s) 620 can be any device configured to allow an exchange of data to and from a network 624. The network 624 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 620 can be configured to support any type of communications protocol desired.

The CPU(s) 602 may also be configured to access the display controller(s) 622 over the system bus 608 to control information sent to one or more displays 626. The display controller(s) 622 sends information to the display(s) 626 to be displayed via one or more video processors 628, which process the information to be displayed into a format suitable for the display(s) 626. The display(s) 626 can include any type of display, including, but not limited to, a cathode ray tube (CRT), a liquid crystal display (LCD), a plasma display, a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read-Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:

1. A radio frequency (RF) integrated circuit (IC) (RFIC), comprising:
a semiconductor die;
a first RF circuit comprising at least one first transistor disposed in a first active region of the semiconductor die;
a second RF circuit comprising at least one second transistor disposed in a second active region of the semiconductor die; and
an isolation material in an isolation region of the semiconductor die between the first active region and the second active region and configured to electrically isolate the first active region from the second active region,
wherein:
each of the first active region and the second active region comprises a semiconductor material comprising a first porosity; and
the isolation material comprises the semiconductor material comprising a second porosity at least twenty percent (20%) higher than the first porosity.
   2. The RFIC of clause 1, wherein the second porosity of the isolation material in the isolation region is in a range of twenty percent (20%) to fifty percent (50%) higher than the first porosity.
   3. The RFIC of clause 1 or clause 2, wherein:
the first RF circuit further comprises a first passive component circuit disposed on a first passive isolation region comprising the isolation material; and
the second RF circuit further comprises a second passive component circuit on a second passive isolation region comprising the isolation material.
   4. The RFIC of clause 3, wherein:
the isolation region is on a first side of the first RF circuit and on a second side of the second RF circuit;
the first passive isolation region is on a second side of the first RF circuit; and
the second passive isolation region is on a first side of the second RF circuit.
   5. The RFIC of any of clause 1 to clause 4, wherein:
the first active region is surrounded by the isolation material, including the isolation region; and
the second active region is surrounded by the isolation material, including the isolation region.
   6. The RFIC of any of clause 1 to clause 5, wherein:
the at least one first transistor in the first active region is disposed on a surface of the semiconductor die; and
the isolation material extends in a direction orthogonal to the surface of the semiconductor die to a depth in a range of fifty (50) micrometers (μm) to one hundred (100) μm.
   7. The RFIC of any of clause 1 to clause 6, wherein:
the first RF circuit comprises a power amplifier circuit; and
the second RF circuit comprises a low-noise amplifier circuit.
   8. A method of forming a radio frequency (RF) integrated circuit (IC) (RFIC), comprising:
forming a semiconductor die;
forming at least one first transistor of a first RF circuit in a first active region of the semiconductor die;
forming at least one second transistor of a second RF circuit in a second active region of the semiconductor die; and
forming an isolation material in an isolation region of the semiconductor die between the first active region and the second active region, the isolation region configured to electrically isolate the first active region from the second active region,
wherein each of the first active region and the second active region comprises a semiconductor material comprising silicon and the isolation material comprises porous silicon with porosity range between 20% and 50%.
   9. The method of clause 8, wherein:
forming the semiconductor die comprises forming a silicide stop layer on the semiconductor die between the first active region and the second active region; and
forming the isolation material in the isolation region comprises:
   forming an oxide layer on the semiconductor die;
   forming a hard mask on the oxide layer, the hard mask comprising an opening in the isolation region;
   selectively porosifying the semiconductor material in the isolation region, wherein the first active region and the second active region are protected by the hard mask;
   removing the hard mask; and
   removing the oxide layer.
      10. The method of clause 9, further comprising porosifying the semiconductor material of the semiconductor die surrounding the first active region and surrounding the second active region.
      11. The method of clause 10, wherein:
the first RF circuit comprises a first passive component circuit on the isolation material surrounding the first active region; and
the second RF circuit comprises a second passive component circuit on the isolation material surrounding the second active region.
   12. A radio frequency (RF) integrated circuit (IC) (RFIC), comprising:
a semiconductor die;
a first RF circuit comprising at least one first transistor disposed in a first active region of the semiconductor die;
a second RF circuit comprising at least one second transistor disposed in a second active region of the semiconductor die; and
an isolation material in an isolation region of the semiconductor die between the first active region and the second active region and configured to electrically isolate the first active region from the second active region,
wherein:
   each of the first active region and the second active region comprises a semiconductor material; and
the isolation material comprises a porosified region of the semiconductor material.
   13. The RFIC of clause 12, wherein:
the semiconductor material in the first active region and in the second active region comprises a monocrystalline semiconductor material; and
the isolation material further comprises the monocrystalline semiconductor material that has been porosified to have a porosity at least twenty percent (20%) higher than a porosity of the monocrystalline semiconductor material in the first active region and in the second active region.
   14. The RFIC of clause 12 or clause 13, wherein:
the first RF circuit further comprises a first passive component circuit disposed on a first passive isolation region comprising the isolation material; and
the second RF circuit further comprises a second passive component circuit on a second passive isolation region comprising the isolation material.
   15. The RFIC of any of clause 12 to clause 14, wherein:
the first active region is surrounded by the isolation material, including the isolation region; and
the second active region is surrounded by the isolation material, including the isolation region.
   16. The RFIC of any of clause 12 to clause 15, wherein:
the at least one first transistor in the first active region is disposed on a surface of the semiconductor die; and
the isolation material extends in a direction orthogonal to the surface of the semiconductor die to a depth in a range of fifty (50) micrometers (μm) to one hundred (100) μm.
   17. The RFIC of any of clause 12 to clause 16, wherein:
the first RF circuit comprises a power amplifier circuit; and
the second RF circuit comprises a low-noise amplifier circuit.
   18. A method of forming a radio frequency (RF) integrated circuit (IC) (RFIC), comprising:
forming a semiconductor die;
forming a first RF circuit comprising at least one first transistor in a first active region of the semiconductor die;
forming a second RF circuit comprising at least one second transistor in a second active region of the semiconductor die; and
forming an isolation material in an isolation region of the semiconductor die between the first active region and the second active region and configured to electrically isolate the first active region from the second active region,
wherein each of the first active region and the second active region comprises a semiconductor material, and the isolation material comprises a porosified region of the semiconductor material.

1. A radio frequency (RF) integrated circuit (IC) (RFIC), comprising:
a semiconductor die;
a first RF circuit comprising at least one first transistor disposed in a first active region of the semiconductor die;
a second RF circuit comprising at least one second transistor disposed in a second active region of the semiconductor die; and
an isolation material in an isolation region of the semiconductor die between the first active region and the second active region and configured to electrically isolate the first active region from the second active region,
wherein:
each of the first active region and the second active region comprises a semiconductor material comprising a first porosity; and
the isolation material comprises the semiconductor material comprising a second porosity at least twenty percent (20%) higher than the first porosity.

2. The RFIC of claim 1, wherein the second porosity of the isolation material in the isolation region is in a range of twenty percent (20%) to fifty percent (50%) higher than the first porosity.

3. The RFIC of claim 1, wherein:
the first RF circuit further comprises a first passive component circuit disposed on a first passive isolation region comprising the isolation material; and
the second RF circuit further comprises a second passive component circuit disposed on a second passive isolation region comprising the isolation material.

4. The RFIC of claim 3, wherein:
the isolation region is on a first side of the first RF circuit and on a second side of the second RF circuit;
the first passive isolation region is on a second side of the first RF circuit; and
the second passive isolation region is on a first side of the second RF circuit.

5. The RFIC of claim 1, wherein:
the first active region is surrounded by the isolation material; and
the second active region is surrounded by the isolation material.

6. The RFIC of claim 1, wherein:
the at least one first transistor in the first active region is disposed on a surface of the semiconductor die; and
the isolation material extends in a direction orthogonal to the surface of the semiconductor die to a depth in a range of fifty (50) micrometers (μm) to one hundred (100) μm.

7. The RFIC of claim 1, wherein:
the first RF circuit comprises a power amplifier circuit; and
the second RF circuit comprises a low-noise amplifier circuit.

8. A method of forming a radio frequency (RF) integrated circuit (IC) (RFIC), comprising:
forming a semiconductor die;
forming at least one first transistor of a first RF circuit in a first active region of the semiconductor die;
forming at least one second transistor of a second RF circuit in a second active region of the semiconductor die; and
forming an isolation material in an isolation region of the semiconductor die between the first active region and the second active region, the isolation region configured to electrically isolate the first active region from the second active region,
wherein each of the first active region and the second active region comprises a semiconductor material comprising a first porosity and the isolation material comprises the semiconductor material comprising a second porosity at least twenty percent (20%) higher than the first porosity.

9. The method of claim 8, wherein:
forming the semiconductor die comprises forming a silicide stop layer on the semiconductor die between the first active region and the second active region; and
forming the isolation material in the isolation region comprises:
forming an oxide layer on the semiconductor die;
forming a hard mask on the oxide layer, the hard mask comprising an opening in the isolation region;
selectively porosifying the semiconductor material in the isolation region, wherein the first active region and the second active region are protected by the hard mask;
removing the hard mask; and
removing the oxide layer.

10. The method of claim 8, further comprising porosifying the semiconductor material of the semiconductor die surrounding the first active region and surrounding the second active region.

11. The method of claim 8, wherein:
the first RF circuit comprises a first passive component circuit disposed on a first passive isolation region comprising the isolation material; and
the second RF circuit comprises a second passive component circuit disposed on a second passive isolation region comprising the isolation material.

12-18. (canceled)
